(19) United States
(12) Patent Application Publication
(10) Pub. No.: US 2026/0343921 A1
(43) Pub. Date: Oct. 29, 2026

(54) JUNCTION PROFILE ENGINEERING THROUGH RADICAL DOPING

(71) Applicant: Taiwan Semiconductor Manufacturing Co., Ltd, Hsinchu (TW)

(72) Inventors: Yu-Chang Lin, Hsinchu (TW); Ming-Hua Yu, Hsinchu (TW); Yi-Rui Chen, Hsinchu (TW)

(21) Appl. No.: 19/732,813

(22) Filed: Jul. 7, 2026

Related U.S. Application Data
(63) Continuation of application No. 18/979,061, filed on Dec. 12, 2024.
(60) Provisional application No. 63/690,130, filed on Sep. 3, 2024.

(51) Int. Cl. H10D 30/01; H10D 30/00

(52) U.S. Cl. CPC H10D 30/0196; H10D 30/0191; H10D 30/502; H10D 30/509

(57) ABSTRACT

A method includes forming a multilayer stack, which includes a plurality of semiconductor nanostructures and a plurality of sacrificial layers. The plurality of semiconductor nanostructures and the plurality of sacrificial layers are located alternatingly. The method further includes laterally recessing the plurality of sacrificial layers to form lateral recesses, performing a doping process to dope a first dopant into the lateral recesses, forming inner spacers in the lateral recesses, performing an anneal process to diffuse the first dopant into the inner spacers, and forming a source/drain region contacting the inner spacers, wherein the source/drain region is electrically coupled to the plurality of semiconductor nanostructures.

### PRIORITY CLAIM AND CROSS-REFERENCE

This application is a continuation of U.S. patent application Ser. No. 18/979,061, filed Dec. 12, 2024, which application claims the benefit of the following provisionally filed U.S. patent application: Application No. 63/690,130, filed on Sep. 3, 2024, and entitled “CONCAVE & CONVEX JUNCTION ENGINEERING BY RADICAL DOPING IN NANOSHEET AND CFET,” which applications are hereby incorporated herein by reference.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs, and for these advances to be realized, similar developments in IC processing and manufacturing are needed. For example, Gate-All-Around (GAA) Transistors have been introduced to replace planar transistors. The structures of the GAA transistors and methods of fabricating the GAA transistors are being developed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 10A, 10B, 11A, 11B, 12A, 12B, 13A, 13B, 14A, 14B, and 15-25 illustrate the views of intermediate stages in the formation of a Gate All-Around (GAA) transistor in accordance with some embodiments.

FIGS. 26-27 illustrate the cross-sectional views of GAA transistors in accordance with alternative embodiments.

FIGS. 28-31 illustrate the dopant profiles of GAA transistors in accordance with some embodiments.

FIG. 32 illustrates a process flow for forming a GAA transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Gate All-Around (GAA) transistors and the methods of forming the GAA transistors are provided. In accordance with some embodiments, the formation process includes performing a doping process, which may be performed after the formation of the recesses for inner spacers, and before the filling of a dielectric layer for forming the inner spacers. The doping process may include a pre-doping process. In the doping process, a dopant (which is of a same conductivity type as the respective source/drain regions) is doped, followed by an anneal process. The anneal process may be performed after the formation of the inner spacers.

By performing the doping process, the profiles of junctions (between source/drain regions and channels) may be adjusted, for example, to form a concave profile or a straight profile. Accordingly, gate control ability may be improved. The dopant concentration at the edges of the semiconductor nanostructures (such as silicon sheets) is also improved, so that the degradation of Drain-Induced-Barrier-Lowering (DIBL) may be reduced.

Although GAA transistors are used as an example to discuss the concept of the present disclosure, the embodiments may be applied on other types of transistors including and not limited to Complementary Field-Effect Transistors (CFETs). Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

In addition, although a p-type transistor is discussed as an example in some parts of the discussion, the concept of the present application is readily available for the formation of n-type transistors, with the conductive types of the corresponding features inversed than in the p-type transistor.

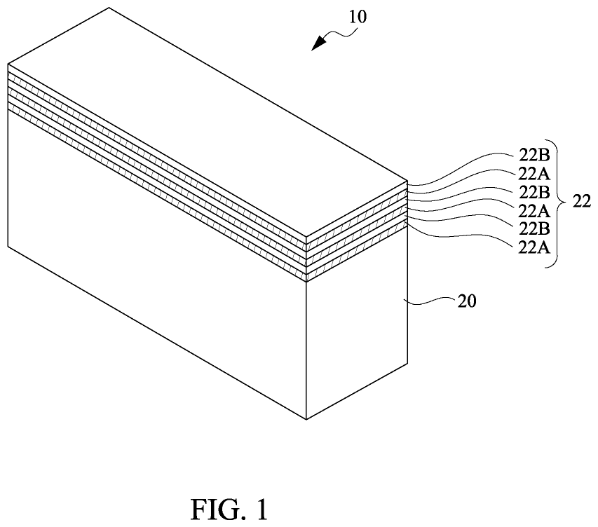

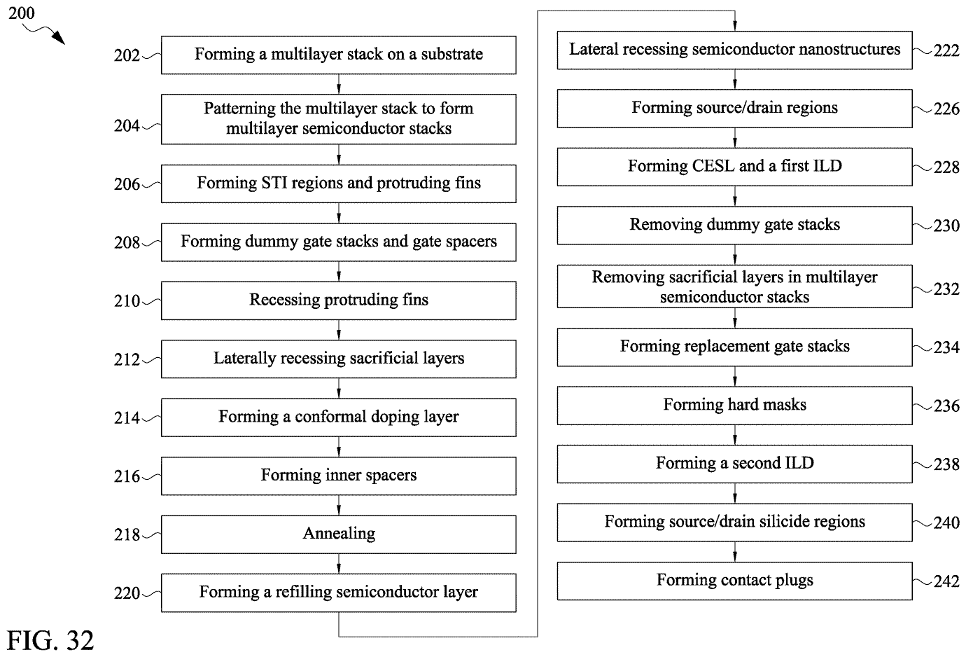

FIGS. 1-4, 5A, 5B, 6A, 6B, 7A, 7B, 8A, 8B, 9A, 9B, 10A, 10B, 11A, 11B, 12A, 12B, 13A, 13B, 14A, 14B, and 15-25 illustrate the views of intermediate stages in the formation of a GAA transistor in accordance with some embodiments of the present disclosure. The corresponding processes are also reflected schematically in the process flow shown in FIG. 32.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor substrate.

In accordance with some embodiments, multilayer stack 22 is formed through a series of deposition processes for depositing alternating materials. The respective process is illustrated as process 202 in the process flow 200 as shown in FIG. 32. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may include Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22A has thickness in the range between about 4 nm and 7 nm, while the second layer 22B has thickness in the range between about 8 nm and 12 nm, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask layer(s) (not shown) formed over multilayer stack 22. These layers are patterned, and are used for the subsequent patterning of multilayer stack 22.

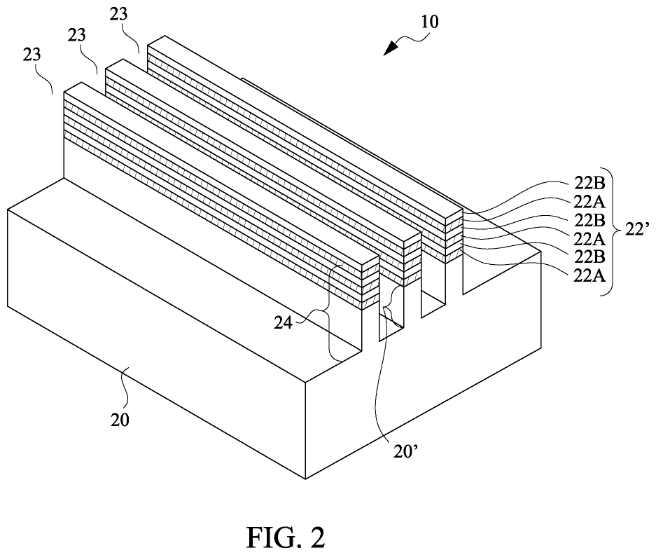

Referring to FIG. 2, multilayer stack 22 and a portion of the underlying substrate 20 are patterned in an etching process(es), so that trenches 23 are formed. The respective process is illustrated as process 204 in the process flow 200 as shown in FIG. 32. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

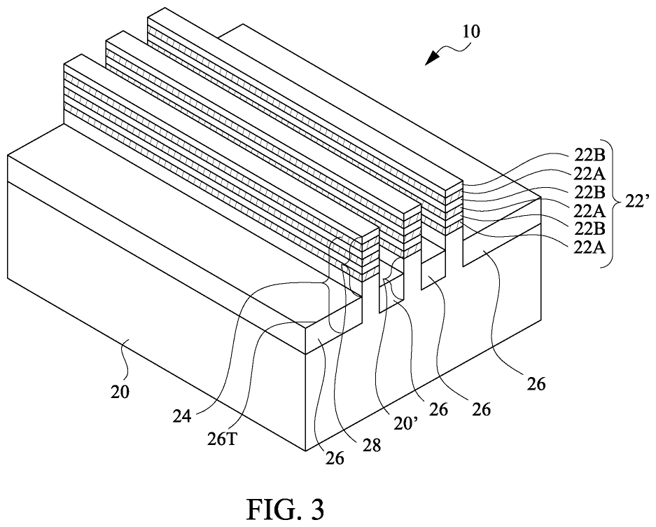

FIG. 3 illustrates the formation of isolation regions 26, which are also referred to as Shallow Trench Isolation (STI) regions throughout the description. The respective process is illustrated as process 206 in the process flow 200 as shown in FIG. 32. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like.

STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

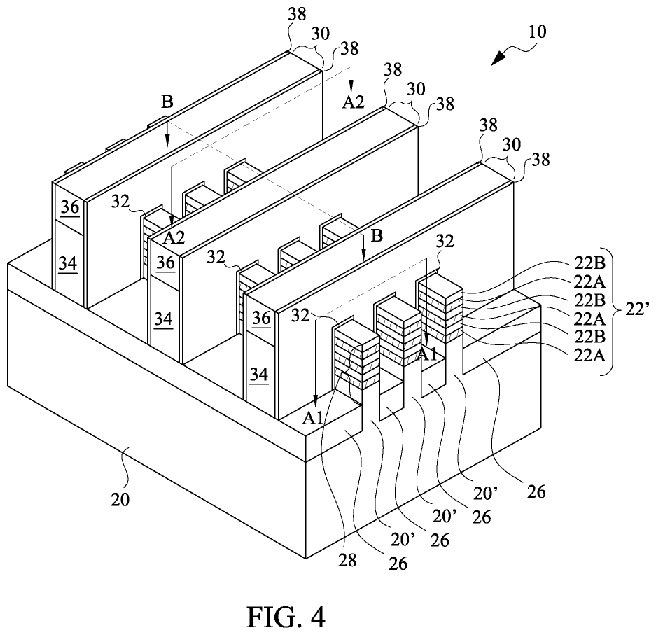

Referring to FIG. 4, dummy gate stacks 30 and gate spacers 38 are formed on the top surfaces and the sidewalls of (protruding) fins 28. The respective process is illustrated as process 208 in the process flow 200 as shown in FIG. 32. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

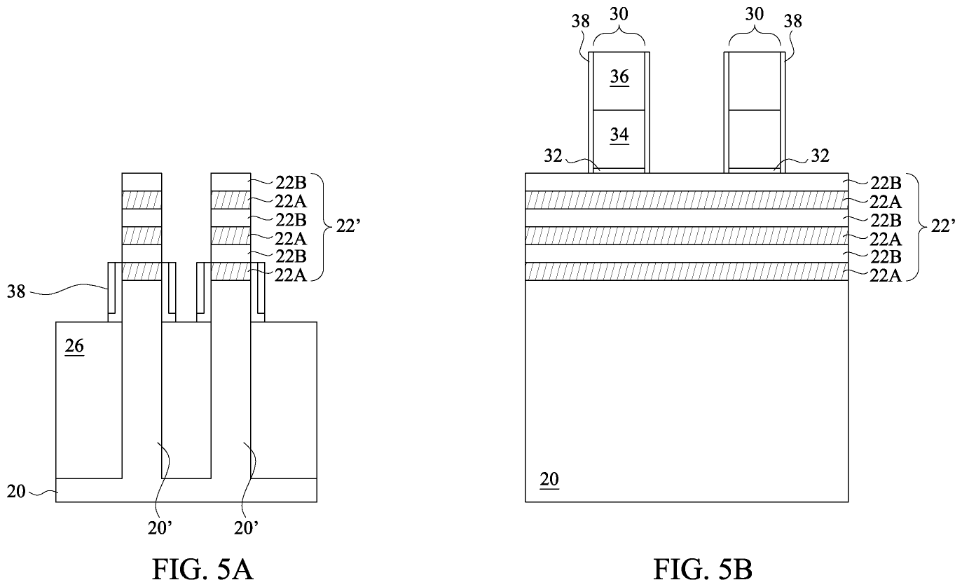

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by dummy gate stacks 30 and gate spacers 38, and is perpendicular to the gate-length direction. FIG. 5B illustrates the reference cross-section B-B in FIG. 4, which reference cross-section is parallel to the lengthwise directions of protruding fins 28.

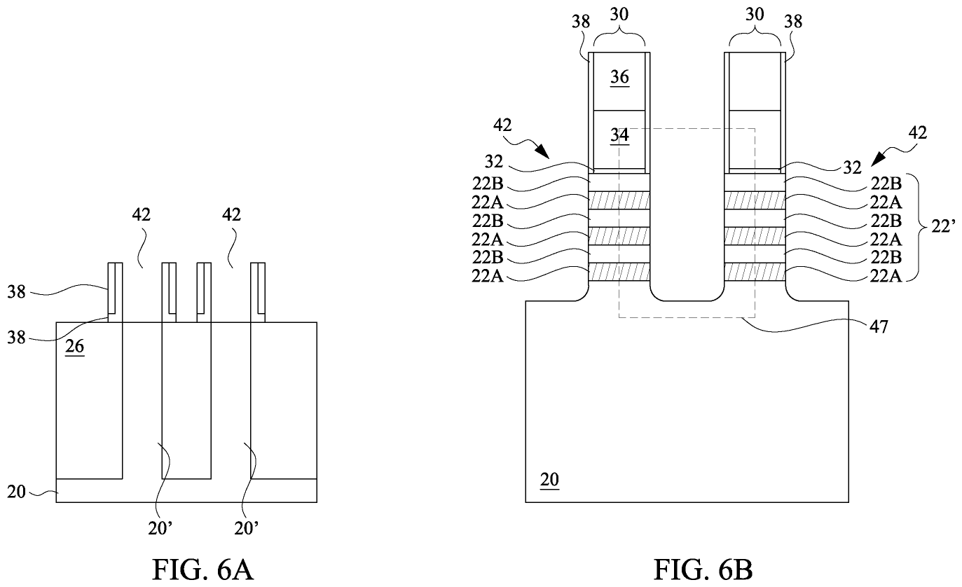

Referring to FIGS. 6A and 6B, the portions of protruding fins 28 (FIG. 4) that are not directly underlying dummy gate stacks 30 and gate spacers 38 are recessed through an etching process to form recesses 42. The respective process is illustrated as process 210 in the process flow 200 as shown in FIG. 32. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

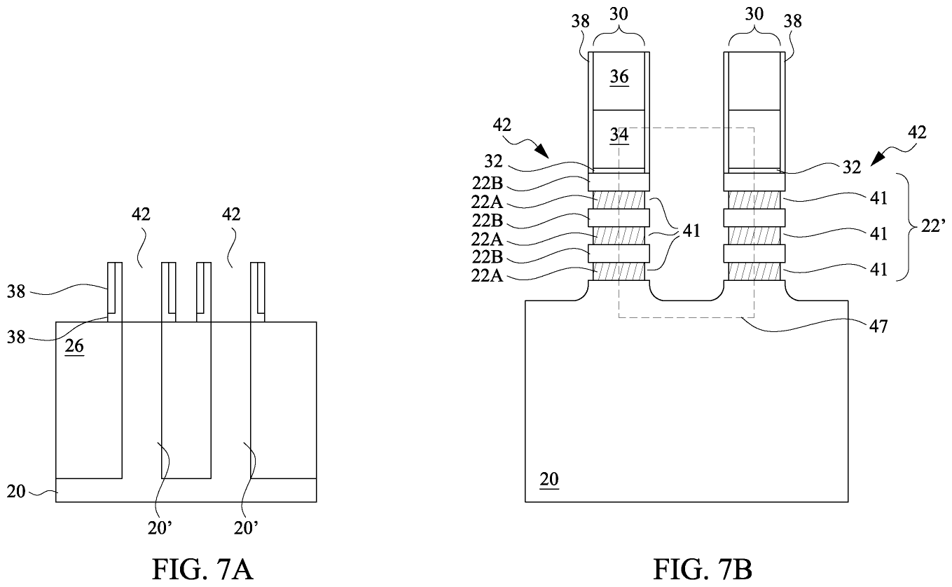

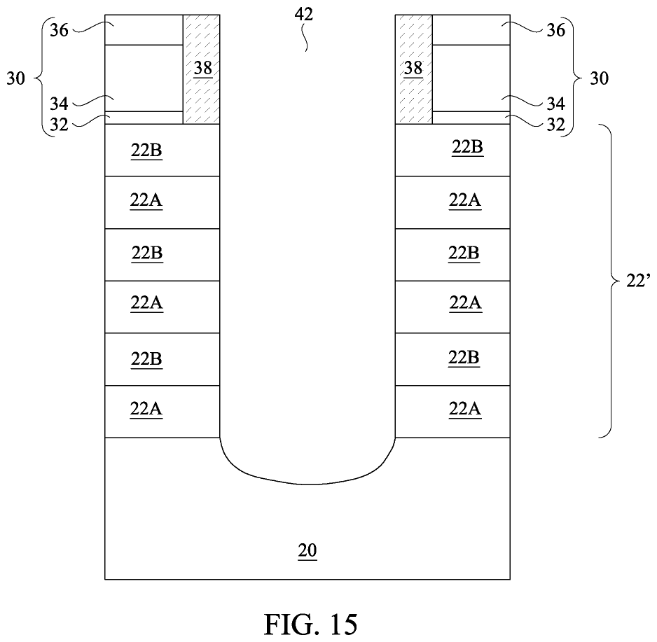

FIGS. 7A and 7B through FIGS. 14A and 14B illustrate the subsequent processes for forming the GAA transistor, with the processes being discussed briefly. The details of these processes are discussed subsequently referring to the magnified views as shown in FIGS. 15-25.

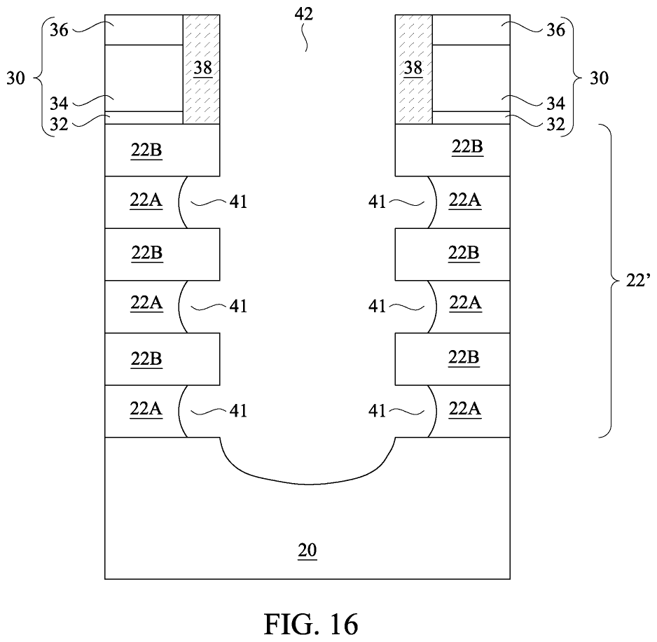

Referring to FIGS. 7A and 7B, sacrificial semiconductor layers 22A are laterally recessed to form lateral recesses 41, which are recessed from the edges of the respective overlying and underlying nanostructures 22B. The details of the recessing process are discussed referring to FIG. 16, as will be discussed subsequently.

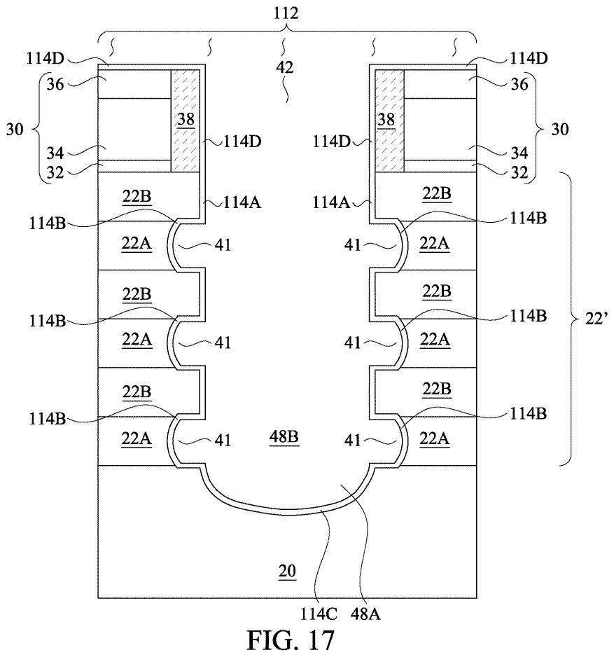

After the lateral recessing, a doping process may be performed to dope a dopant and to form a dopant-rich layer, which may be a conformal doping layer. The details are discussed referring to FIG. 17, as will be discussed subsequently.

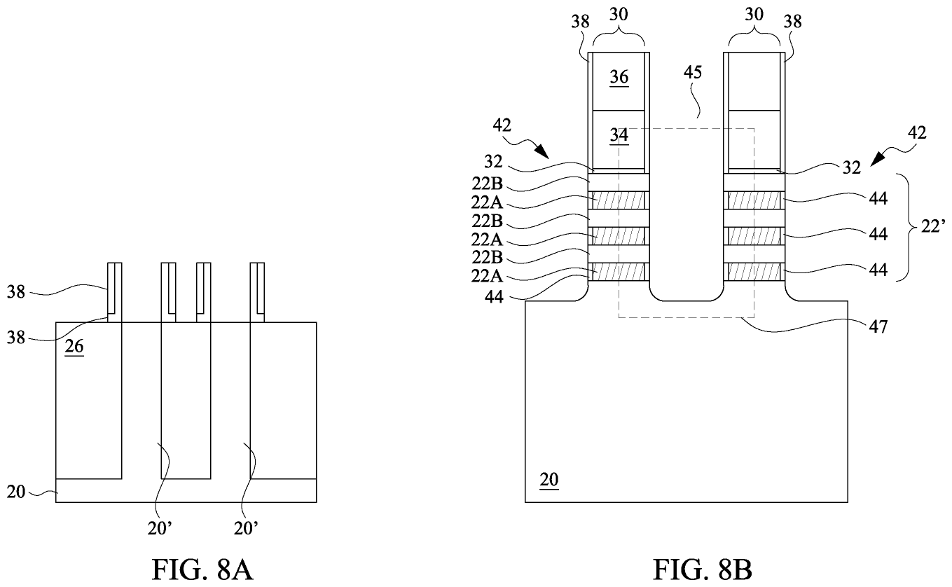

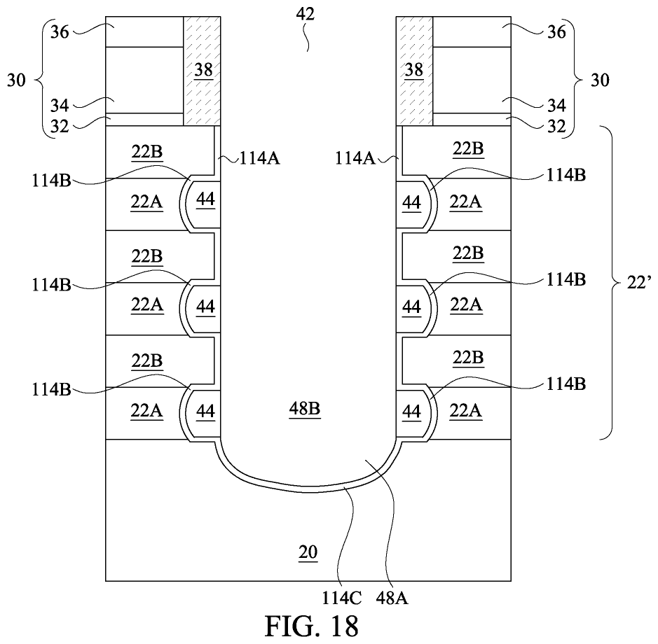

Referring to FIGS. 8A and 8B, inner spacers 44 are formed. The details are discussed referring to FIG. 18, as will be discussed subsequently.

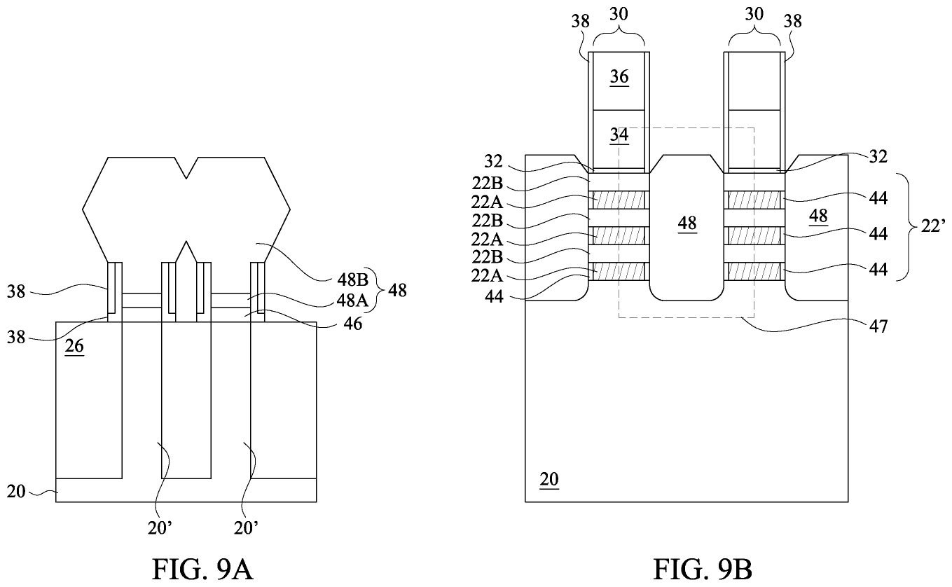

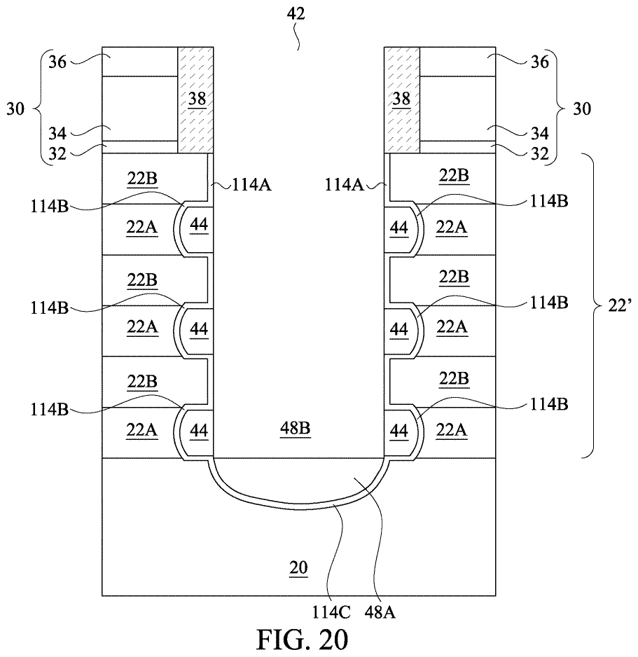

Referring to FIGS. 9A and 9B, source/drain regions 48 are formed in recesses 42, for example, through epitaxy processes. The details are discussed referring to FIGS. 20-22, as will be discussed subsequently.

FIGS. 15-25 illustrate the details of processes as shown in FIGS. 7A and 7B through FIGS. 14A and 14B in accordance with some embodiments. The amplified views of the regions 47 in FIGS. 7A and 7B through FIGS. 14A and 14B are illustrated in FIGS. 15-25.

Referring to FIG. 15, a multilayer stack including three stacked nanostructures 22B is illustrated as an example. The number of nanostructures 22B in a stack may be any other number, for example, ranging from 2 to about 5. The height (thickness) of nanostructures 22B may be in the range between about 3 nm and about 15 nm. The height (thickness) of sacrificial layers 22A (hence the height/thickness of the replacement gate stacks subsequently replacing the sacrificial layers 22A) may also be in the range between about 3 nm and about 15 nm.

Referring to FIG. 16, lateral recesses 41 are formed. The respective process is illustrated as process 212 in the process flow 200 as shown in FIG. 32. The corresponding process is also illustrated in FIG. 7B. In accordance with some embodiments, the sidewalls of sacrificial layers 22A facing recesses 41 have concave profiles.

The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, a spin-on process, or the like.

In accordance with alternative embodiments, the lateral recessing of sacrificial semiconductor layers 22A is performed through an isotropic dry etching process or a combination of a dry etching process and a wet etching process.

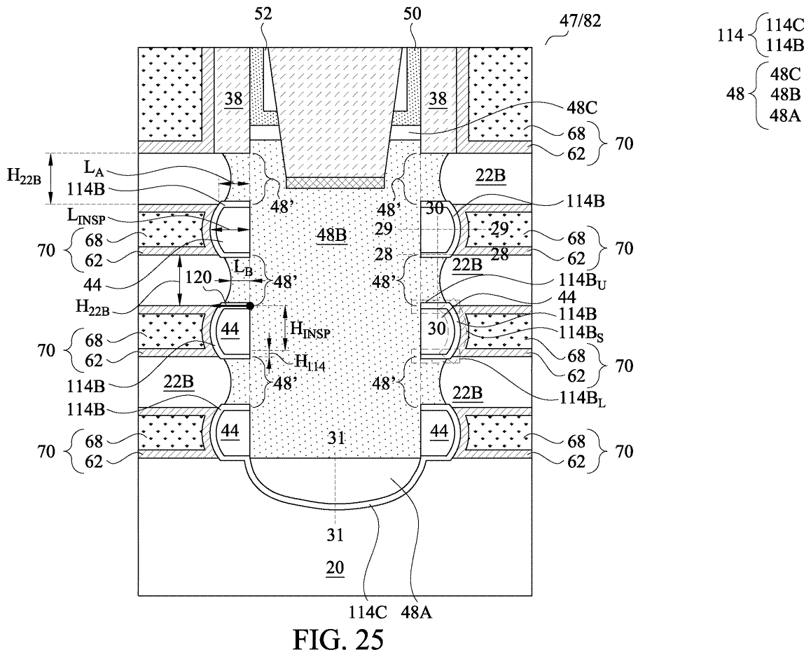

FIG. 17 illustrates radical pre-doping process 112 to form a dopant-rich layer 114 in accordance with some embodiments. The respective process is illustrated as process 214 in the process flow 200 as shown in FIG. 32. The radical pre-doping process 112 is performed by soaking the respective wafer in a doping gas. The doping gas comprises a dopant(s) that is of the same conductivity as the source/drain regions 48 (FIG. 25) formed in subsequent processes. For example, when the source/drain regions 48 are p-type source/drain regions, the dopant (referred to as a pre-doping dopant hereinafter) is of p-type, and may comprise boron, indium, and/or the like. When the source/drain regions 48 are n-type source/drain regions, the pre-doping dopant is of n-type, and may comprise phosphorous, arsenic, antimony, and/or the like. In subsequent discussion, boron is discussed as the dopant, while other dopants may be used.

In accordance with some embodiments in which boron is used as the pre-doping dopant, the doping gas may comprise BH₃, while other types of boron-containing gases may also be used.

The pre-doping process 112 is performed using a plasma doping process, wherein no bias power is applied. Also, the plasma generated from the doping gas may not (or may) be filtered to remove ions. When the plasma is not filtered, the ions in the plasma are also in contact with the wafer. It is appreciated that the regions to be doped are inside recesses 42, and radicals have better ability of going into recesses than ions. Accordingly, rich radicals exist in recesses 42. The ions, on the other hand, are less likely to be doped to the features exposed to lateral recesses. With no bias power applied, the damage to the exposed features is minimized.

The pre-doping process 112 may be performed with the wafer temperature being in the range between room temperature (for example, about 20° C.) and about 400° C. The pressure of the respective chamber may be in the range between about 1 torr and about 500 torr. The pre-doping process 112 may be stopped when the dopant-rich layers 114 has a dopant concentration (such as a peak dopant concentration in the doped regions) in the range between about 1E19/cm³ and about 1E21/cm³.

Radicals have good ability of bonding with other materials. Accordingly, the radicals of the pre-doping dopant will diffuse into and bond with the surface layers of the exposed materials to form dopant-rich layers 114. Dopant-rich layers 114 may be conformal or substantially conformal, for example, with thickness variation being smaller than about 50 percent, smaller than about 20 percent, or smaller than about 10 percent (of the thickness of the thickest portion).

The dopant-rich layers 114 comprise the pre-doping dopant and the material of the corresponding features whose surfaces are exposed to the doping gas. For example, the dopant-rich layers 114 may comprise portions 114A on semiconductor nanostructure 22B, portions 114B on sacrificial layers 22A, portions 114C on bulk semiconductor substrate 20, and portions 114D on gate spacers 38 and hard masks 36. Portions 114A and 114D may thus comprise silicon with boron doped therein. Portions 114B may comprise SiGe with boron doped therein. The portions 114D on gate spacers 38 may comprise the dielectric material of gate spacers 38 with boron doped therein. The portions 114D on hard masks 36 may comprise the dielectric material of hard masks 36 with boron doped therein. Portions 114A, 114B, 114C, and 114D are also referred to as dopant-rich layers.

Referring to FIG. 18, inner spacers 44 are formed. The corresponding processes are also illustrated in FIG. 8B. The respective process is illustrated as process 216 in the process flow 200 as shown in FIG. 32. In accordance with some embodiments, the formation of inner spacers 44 includes depositing a conformal dielectric layer, which extends into the lateral recesses 41. Next, an etching process (also referred to as a spacer trimming process) is performed to trim the portions of the spacer layer outside of the lateral recesses 41, leaving the portions of the spacer layer in the lateral recesses 41. The remaining portions of the spacer layer are inner spacers 44. Inner spacers 44 may be single-layer spacers, or may include a plurality of sub layers (such as two or three sub layers).

At the time the structure shown in FIG. 18 is formed, the portions of dopant-rich layer 114D (FIG. 17) on gate spacers 38 and hard masks 36 have been removed, for example, by the etching process for forming inner spacers 44 and the cleaning processes performed before the anneal process 118. In some embodiments, portion 114C may also be removed, or left unremoved.

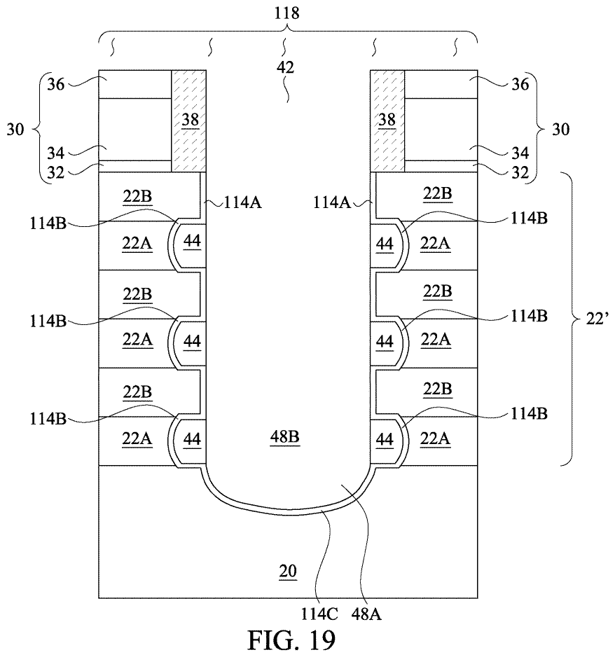

Referring to FIG. 19, after the formation of inner spacers 44, an anneal process 118 is performed to diffuse the pre-doping dopant deeper into inner spacers 44, semiconductor nanostructures 22B, and sacrificial layers 22A. The respective process is illustrated as process 218 in the process flow 200 as shown in FIG. 32. Due to the anneal process 118, the pre-doping dopant diffuses into the nearby regions, and the thickness of the dopant-rich layers 114 is increased. For example, after the anneal process 118, the dopant-rich layers 114B will comprise dielectric portions as parts of the inner spacers 44, semiconductor portions as parts of sacrificial layers 22A, and semiconductor portions as parts of semiconductor nanostructures 22B. The dopant-rich layer 114C may also diffuse into bulk substrate 20.

In accordance with some embodiments, the anneal process 118 is performed through spike annealing, for example, with the anneal duration being shorter than about 2 seconds, and may be in the range between about 0.5 seconds and about 1.5 seconds. The wafer temperature may be in the range between about 950° C. and about 1,100° C. Other annealing methods such as oven annealing, laser annealing, or the like may also be used.

In accordance with some embodiments, as shown in FIG. 19, the anneal process 118 is performed at a time after the formation of inner spacers 44. In accordance with alternative embodiments, the anneal process 118 may be performed after the deposition of the dielectric layer that is used for forming inner spacers 44, and before the etching of the dielectric layer to form inner spacer 44.

Referring to FIG. 20, refilling semiconductor layer 48A (also referred to as a dummy semiconductor layer or layer L0) is deposited, for example, through a bottom-up deposition process. The respective process is illustrated as process 220 in the process flow 200 as shown in FIG. 32. Dummy semiconductor layer 48A may comprise silicon, and may be free from elements such as germanium, carbon, and the like.

Dummy semiconductor layer 48A may also be an intrinsic layer that is free from n-type dopants (such as phosphorous, arsenic, and antimony) and p-type dopants (such as boron, indium, and the like). In accordance with alternative embodiments, dummy semiconductor layers 48A may comprise an n-type or p-type dopant, which is of the same conductivity type as the subsequently formed source/drain regions 48. If doped, the dopant concentration of the n-type or p-type dopant may be lower than that in the subsequently deposited layers of source/drain regions 48. In the embodiments in which portion 114C is removed, dummy semiconductor layer 48A physically contacts substrate 20.

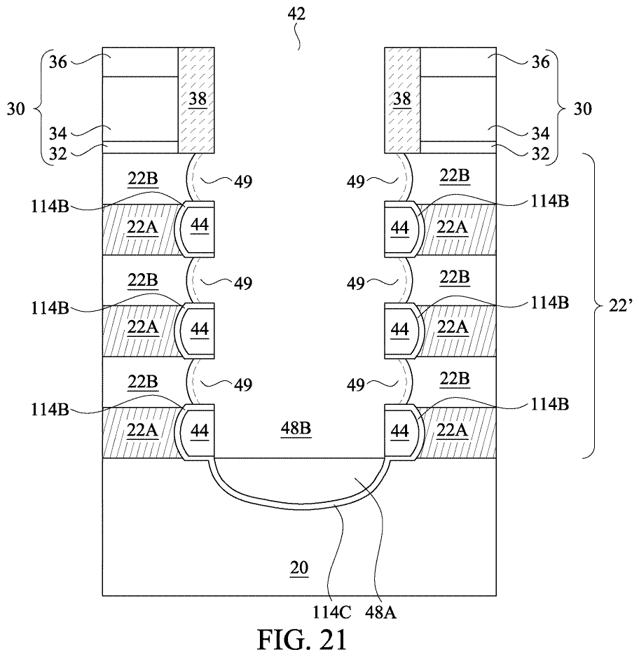

FIG. 21 illustrates the lateral recessing of nanostructures 22B to form lateral recesses 49 in accordance with some embodiments. The respective process is illustrated as process 222 in the process flow 200 as shown in FIG. 32. The lateral recessing may be performed through an isotropic etching process. After the lateral recessing processes, the outer edges of nanostructures 22B may be directly underlying (and overlapped by) gate spacers 38, and may overlap some of inner spacers 44 and/or overlapped by some other inner spacers 44.

Dashed lines are illustrated to show that the lateral recessing may be recess to different lateral distances. In accordance with alternative embodiments, the lateral recessing process is skipped.

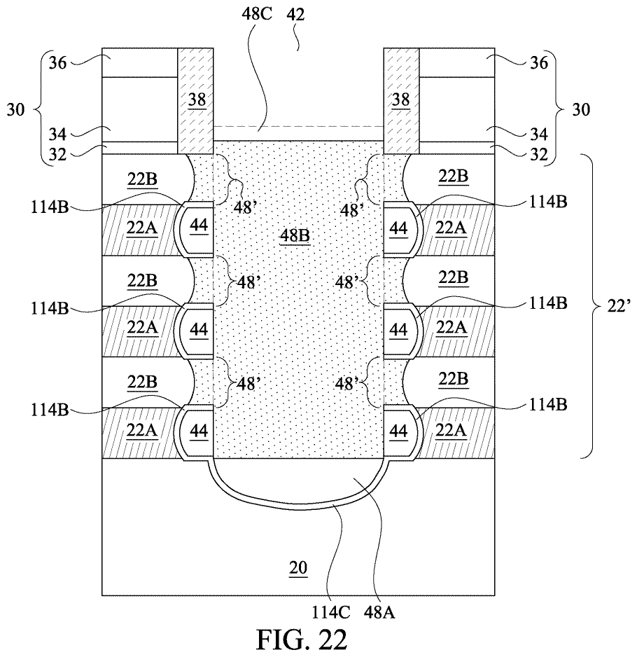

FIG. 22 illustrates the formation of source/drain regions 48B, which is performed through selective epitaxy. The respective process is illustrated as process 226 in the process flow 200 as shown in FIG. 32. The corresponding structure is also shown in FIG. 9B. In accordance with some embodiments, source/drain regions 48 comprises a dopant having a same conductivity type as that is introduced by pre-doping process 112. For example, source/drain regions 48 may be p-type regions and may comprise boron. The dopant of the source/drain regions 48B may be the same as, or different from, the dopant of the dopant-rich layer 114B. For example, dopant-rich layer 114B may comprise boron, and source/drain regions 48B may comprises boron and/or indium.

Due to the thermal processes in the epitaxy, the dopant in the dopant-rich layers 114B further diffuse into portions 48′ of source/drain regions 48. Accordingly, the resulting dopant-rich layers 114B includes dielectric portions in inner spacers 44, and semiconductor portions in portions 48B.

Source/drain regions 48 may include a plurality of sub layers. For example, first sub layers (which are parts of the source/drain portions 48′) may be selectively deposited to fill lateral recesses 49, and hence are also referred to as refilling semiconductor layers. Portions 48′ are also referred to as source/drain extensions or Lightly-doped Drain/source (LDD) regions. Portions 48′ include the refilling semiconductor layers and parts of the semiconductor nanostructures 22B that are diffused to have the same conductivity type as the respective transistor. In accordance with some embodiments, the refilling semiconductor layers comprise silicon and a dopant, which has the same conductivity type as other parts of the source/drain regions 48.

In accordance with some embodiments, the refilling semiconductor layers may comprise silicon boron, and may be free from germanium therein. The formation of the refilling semiconductor layers has the function of improving the junction control since the doped refilling semiconductor layers, which replace the original parts of semiconductor nanostructures 22B, are formed closer to the respective channels of the GAA transistor.

After the lateral recesses 49 are refilled, more semiconductor layer(s) are further formed to form source/drain regions 48B. When the source/drain regions 48 are p-type regions of a p-type transistor, semiconductor layers 48B may comprise silicon, SiGe, or Ge, and further include a p-type dopant such as boron, indium, or combinations thereof. The semiconductor layers 48B may have a p-type dopant concentration in a range between about 1E20/cm³ and about 3E21/cm³. Semiconductor layers 48B may also have a plurality of (sub) semiconductor layers with different p-type dopant concentrations (or n-type dopant concentrations if the GAA transistor is an n-type transistor) and/or different germanium atomic percentages.

FIG. 22 further illustrates the formation of capping layer 48C in accordance with some embodiments, for example, through a selective epitaxy process. In accordance with some embodiments, capping layer 48C comprises silicon and is free from germanium. Capping layer 48C may also include SiGe with a lower germanium atomic percentage than that in semiconductor layers 48B. The boron concentration in capping layer 48C may also be lower than the boron concentration in semiconductor layer 48B, for example, by one order or more. In accordance with alternative embodiments, capping layer 48C is not formed. Accordingly, capping layer 48C is illustrated as being dashed to indicate that it may be, or may not be, formed.

Source/drain layers 48B and 48C (if formed) collectively form parts of source/drain regions 48. Refilling semiconductor layer 48A may or may not be considered as a part of the source/drain region 48, depending on whether refilling semiconductor layer 48A is doped or not, and the doping type if doped.

Due to the elevated temperature in the epitaxy process, the dopants (such as boron) introduced by the pre-doping process 112 and the dopant in source/drain region 48 are diffused into semiconductor nanostructure 22B and sacrificial layers 22A. Accordingly, the sidewalls of source/drain regions 48B (which are also the sidewalls of source/drain regions 48) that are in contact with the channel regions of the corresponding GAA transistor may have different profiles resulted from the above processes. It is appreciated that due to the diffusion, the resulting source/drain regions may also comprise some portions of semiconductor nanostructures 22B, which portions have the conductivity type inverted due to the diffusion.

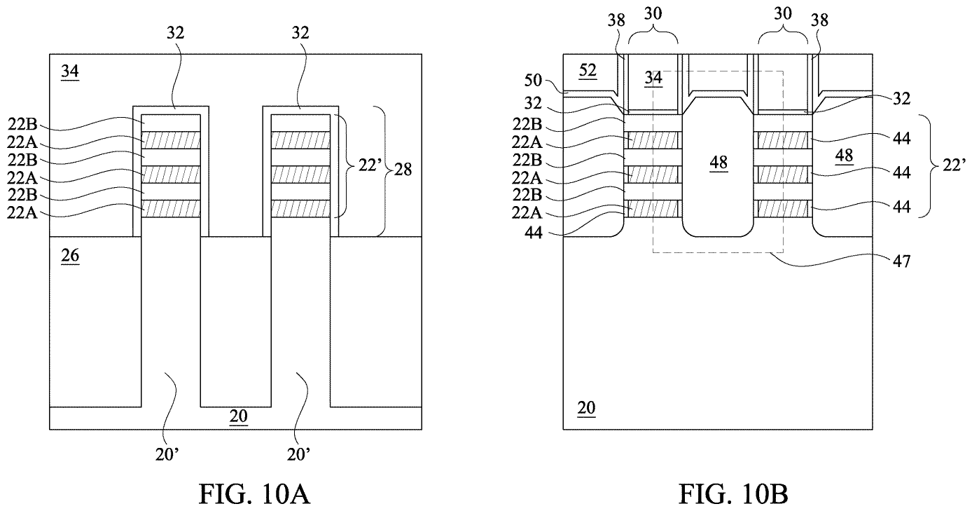

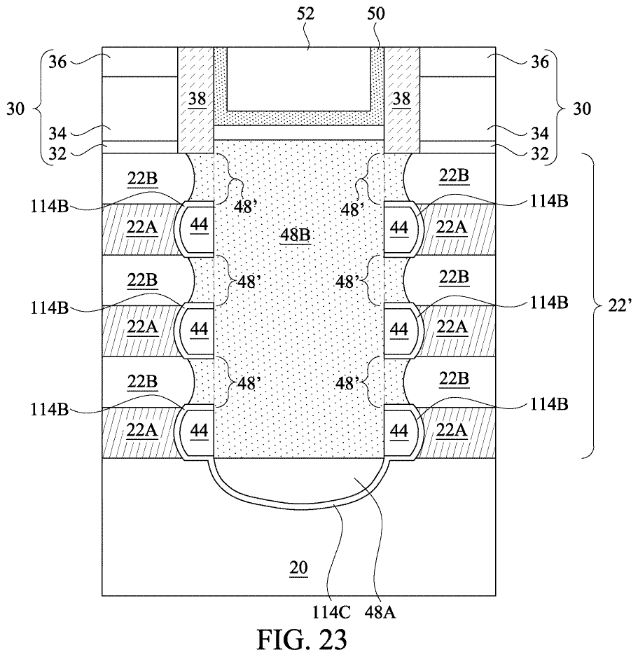

FIGS. 10A and 10B illustrate the cross-sectional views of the structure after the formation of Contact Etch Stop Layer (CESL) 50 and Inter-Layer Dielectric (ILD) 52. The respective process is illustrated as process 228 in the process flow 200 as shown in FIG. 32. The corresponding structure is also shown in FIG. 23. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be silicon oxide, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. In accordance with some embodiments, the planarization process may remove hard masks 36 to reveal dummy gate electrodes 34, as shown in FIG. 10A. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

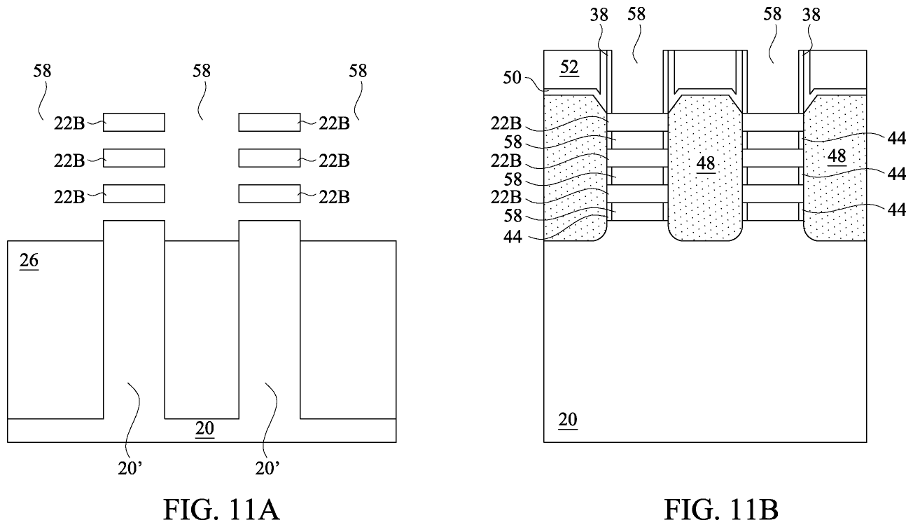

Next, dummy gate electrodes 34 and dummy gate dielectrics 32 (and hard masks 36, if remaining) are removed in one or more etching processes, so that recesses are formed, as shown in FIGS. 11A and 11B. The respective process is illustrated as process 230 in the process flow 200 as shown in FIG. 32.

Sacrificial layers 22A are then removed to extend recesses 58 between nanostructures 22B. The respective process is illustrated as process 232 in the process flow 200 as shown in FIG. 32. Sacrificial layers 22A may be removed by performing an isotropic etching process such as a wet etching process using etchants which are selective to the materials of sacrificial layers 22A, while nanostructures 22B, substrate 20, and STI regions 26 remain relatively un-etched as compared to sacrificial layers 22A.

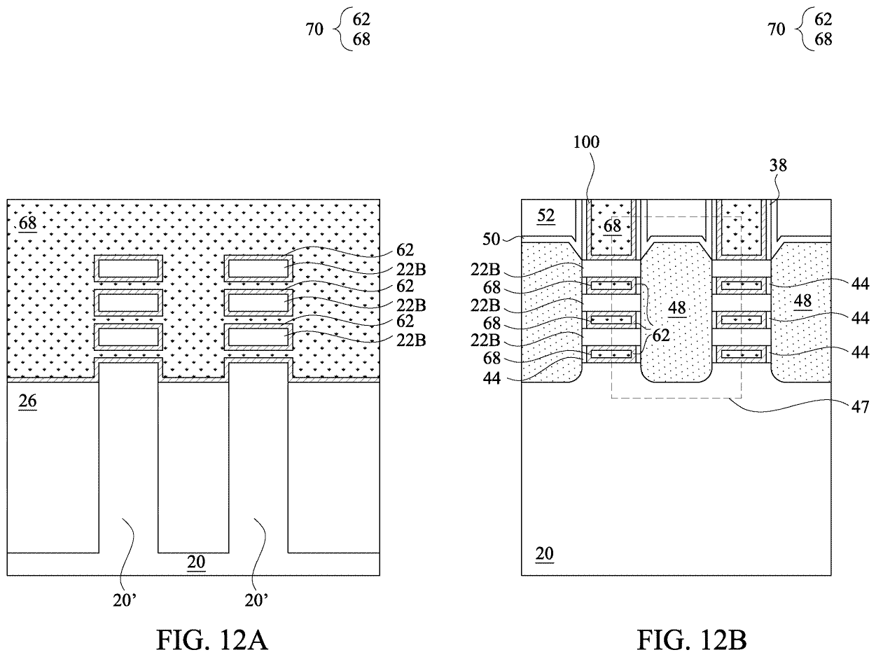

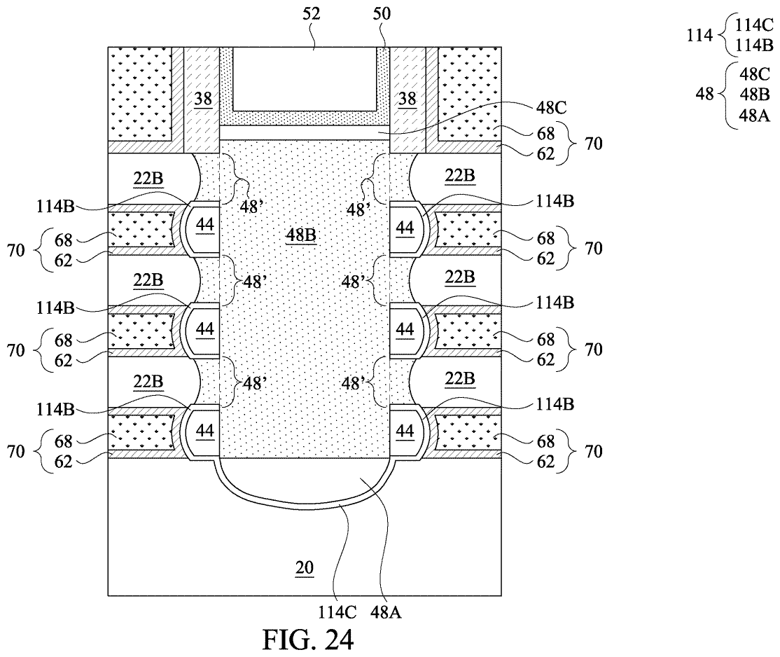

Referring to FIGS. 12A and 12B, gate dielectrics 62 and gate electrodes 68 are formed, hence forming replacement gate stacks 70. The respective process is illustrated as process 234 in the process flow 200 as shown in FIG. 32. The corresponding structure is also shown in FIG. 24. In accordance with some embodiments, each of gate dielectric 62 includes an interfacial layer and a high-k dielectric layer on the interfacial layer. The interfacial layer may be formed of or comprises silicon oxide. In accordance with some embodiments, the high-k dielectric layer comprises one or more dielectric layers. For example, the high-k dielectric layer may include a metal oxide or a silicate of hafnium, aluminum, zirconium, lanthanum, manganese, barium, titanium, lead, and combinations thereof.

Gate electrodes 68 are also formed. In the formation process, conductive layers are first formed on the high-k dielectric layer, and the remaining portions of recesses 58 are filled. Gate electrodes 68 may include a metal-containing material such as TiN, TaN, TiAl, TiAlC, cobalt, ruthenium, aluminum, tungsten, combinations thereof, and/or multilayers thereof.

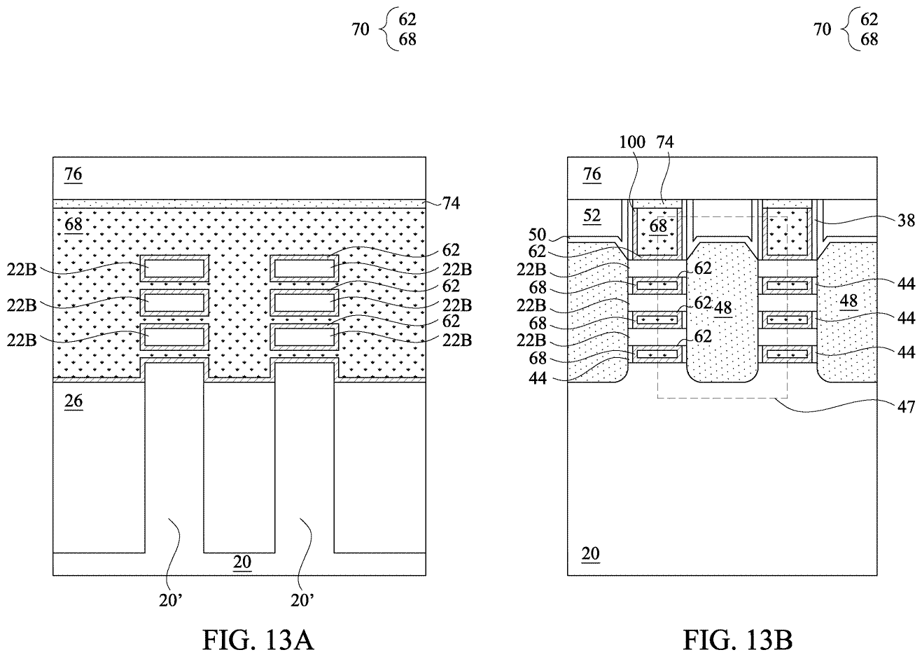

In the processes shown in FIGS. 13A and 13B, gate stacks 70 are recessed, so that recesses are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52. The respective process is illustrated as process 236 in the process flow 200 as shown in FIG. 32.

As further illustrated by FIGS. 13A and 13B, ILD 76 is deposited over ILD 52 and over gate masks 74. The respective process is illustrated as process 238 in the process flow 200 as shown in FIG. 32. An etch stop layer (not shown) may be (or may not be) deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

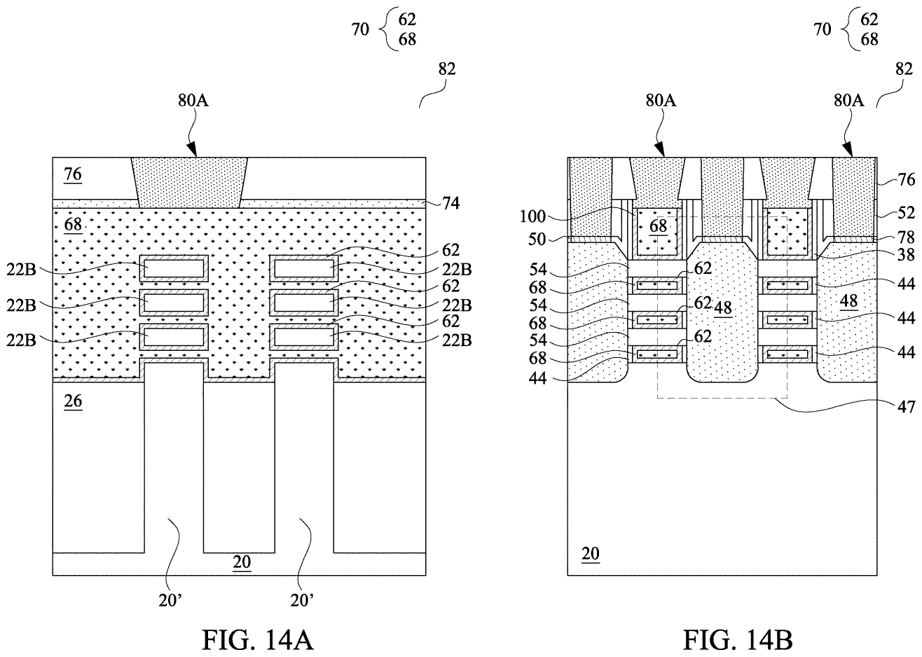

In FIGS. 14A and 14B, ILD 76, ILD 52, CESL 50, and gate masks 74 are etched to form recesses (occupied by contact plugs 80A and 80B) exposing surfaces of source/drain regions 48 and/or gate stacks 70. The recesses may be formed through etching using an anisotropic etching process, such as RIE, NBE, or the like. Although FIG. 14B illustrates that contact plugs 80A and 80B are in a same cross-section, in various embodiments, contact plugs 80A and 80B may be formed in different cross-sections, thereby reducing the risk of shorting with each other.

After the recesses are formed, silicide regions 78 are formed over source/drain regions 48. The respective process is illustrated as process 240 in the process flow 200 as shown in FIG. 32. Contact plugs 80B are then formed over silicide regions 78. Also, contact plugs 80A (may also be referred to as gate contact plugs) are also formed in the recesses, and are over and contacting gate electrodes 68. The respective process is illustrated as process 242 in the process flow 200 as shown in FIG. 32. The corresponding structure is also shown in FIG. 25. Transistor 82 is thus formed. It is noted that the details of the source/drain regions 48 and the dopant-rich layer 114 are not shown in FIGS. 14A and 14B, and the details may be found referring to FIG. 25.

FIGS. 25, 26, and 27 illustrate that the sidewalls of portions 48B′ of source/drain regions 48 contacting the channel regions (which have an opposite conductivity type than the source/drain region portions) have a concave profile, a straight profile, and a convex profile, respectively. What profile is formed is related to a variety of factors including, and not limited to, the dopant concentration of the pre-doping, the recessing depth of the lateral recess 49, the doping concentrations of the dopant introduced by the epitaxy of the source/drain regions, the temperature and the duration of the anneal process 118 and the epitaxy process, and the like.

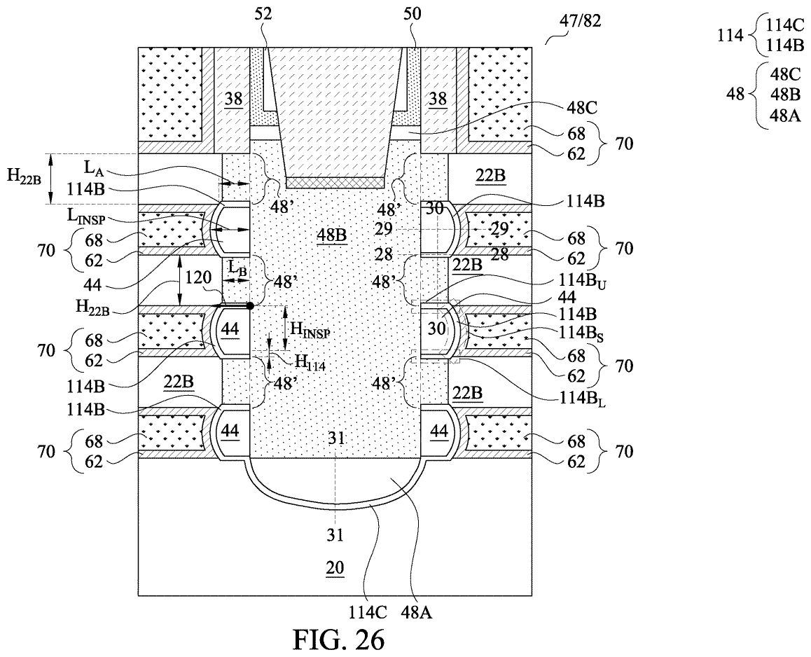

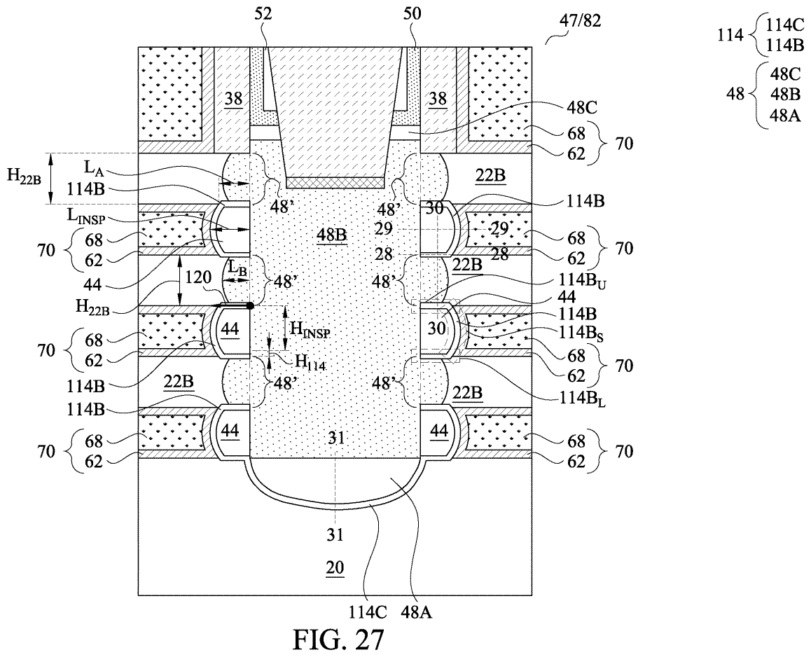

For example, a higher dopant concentration of the pre-doping dopant and shallower lateral recesses 49 (or no lateral recessing) may result in the concave profile (FIG. 25). A lower dopant concentration of the pre-doping dopant and less-shallower lateral recesses 49 may result in the straight profile (FIG. 26). An even-lower dopant concentration of the pre-doping dopant and deeper lateral recesses 49 may result in the convex profile (FIG. 27).

By adjusting the processes as aforementioned, a concave profile as shown in FIG. 25 may be achieve. Due to the concave profile, the dopant introduced by the pre-doping process causes boron-rich layer 114 to be formed at the top surface and the bottom surface of semiconductor nanostructures 22B, and are laterally closer to gate electrodes 68. This improves the gate control. On the other hand, due to the concave profile, the source/drain regions do not have protrusions (like convex profiles) that may extend too much into semiconductor nanostructures 22B and cause the degradation of the DIBL.

In FIGS. 25, 26, and 27, value L_{INSP} is the lateral thickness of inner spacers 44. Value L_{A} is the lateral length of boron-rich layer 114B measured at the top surface and/or bottom surfaces of nanostructures 22B. Value L_{B} is the lateral length of boron (source/drain) front-end junction (the length of parts of the source/drain region directly underling/overlying inner spacers 44). Value L_{B} is also the length of the source/drain extensions 48′, which are also referred to as LDD regions. Value H₁₁₄ is the height (thickness) of boron-rich layer 114B measured at the top surface and/or the bottom surfaces of nanostructures 22B. Value H_{INSP} is the height (thickness) of inner spacers 44. Value H_{22B} is the height (thickness) of nanostructures 22B.

As shown in FIGS. 25, 26, and 27, each (except the topmost ones) of dopant-rich layers 114B may comprise portions 114B_{U}, 114B_{L} and 114B_{S}. Each of 114B_{U} and 114B_{L} comprises a semiconductor portion and a dielectric portion. The semiconductor portions are the portions of dopant-rich layers 114B in LDD regions 48′. The dielectric portions are the portions of dopant-rich layers 114B in inner spacers 44. A portion 114B_{S} comprises a portion of the inner spacer 44, and a portion of gate dielectric 62, both being dielectric portions/layers.

Length L_{A} is desirable to be kept in certain range. When length L_{A} is too small such as smaller than 1 nm, the corresponding LDD region is too small, and the benefit of improving gate control and drive current is too small. When length L_{A} is too large such as greater than 10 nm, the DIBL performance is degraded too much. In accordance with some embodiments, length L_{A} may be in the range between about 1 nm and about 10 nm.

Height/thickness H₁₁₄ is desirable to be kept in certain range. When height/thickness H₁₁₄ is too small such as smaller than 1 nm, the benefit of improving gate control and drive current is too small. When height/thickness H₁₁₄ is too large such as greater than 5 nm, the DIBL performance is degraded too much. In accordance with some embodiments, the height/thickness H₁₁₄ may be in the range between about 1 nm and about 5 nm. The boron concentration in the LDD regions 48′ (other than the dopant-rich layers 114B) may be in the range between about 1E19/cm³ and about 1E21/cm³. The boron concentration in the parts of the dopant-rich layers 114B in the LDD regions 48′ may be greater than about 1E21/cm³.

Referring to FIG. 25, which illustrates a concave profile, there exists the relationship L_{B}<L_{A}<=L_{INSP}, and H_{22B}>2H₁₁₄. Referring to FIG. 26, which illustrates a straight profile, there exists the relationship L_{B}=L_{A}<=L_{INSP}, and H_{22B}>2H₁₁₄. Referring to FIG. 27, which illustrates a convex profile, there may exist the relationship L_{A}<L_{INSP}<L_{B}, L_{A}<L_{INSP}=L_{B}, or L_{A}<L_{B}<L_{INSP}. Also, there exists the relationship H_{22B}>2H₁₁₄.

In accordance with some embodiments, the abruptness of the LDD regions 48′, which abruptness is the reduction rate of the boron concentration along arrows 120 (FIGS. 25, 26, and 27), may be smaller than about 4 nm/decade. The abruptness also corresponds to the lateral distance during which the boron concentration drops from about 1E20/cm³ to about 1E19/cm³.

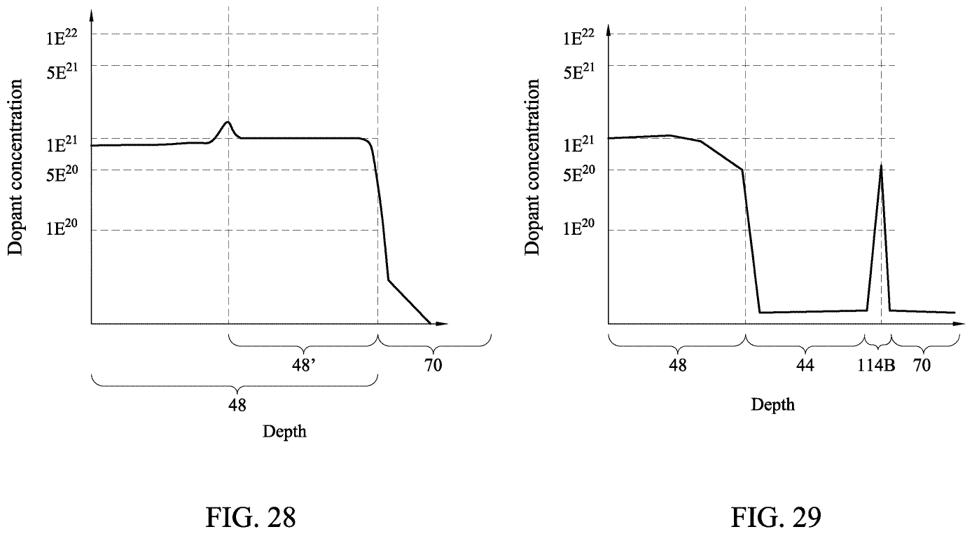

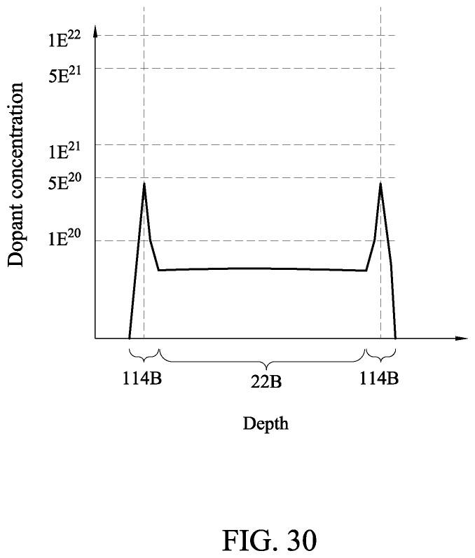

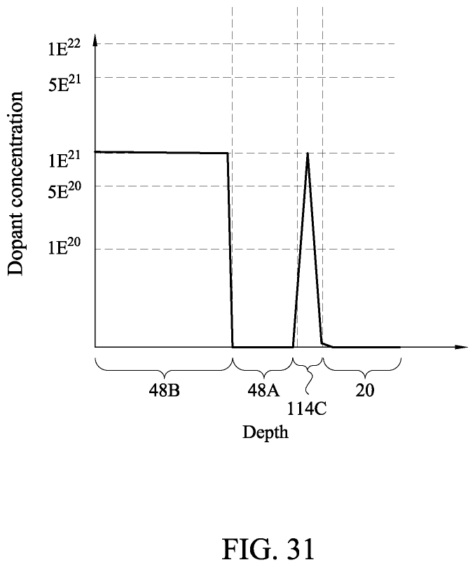

FIGS. 28, 29, 30, and 31 illustrate the schematic dopant profiles in each of the structures shown in FIGS. 25, 26, and 27, wherein dopant concentrations are illustrated as functions of the depths (with the corresponding regions along the depths marked). The dopant profiles in FIGS. 28, 29, 30, and 31 are obtained from cross-sections 28-28, 29-29, 30-30, and 31-31, respectively, in FIGS. 25, 26, and 27.

The profiles may be found using, for example, Transmission Electron Microscopy (TEM), Energy-Dispersive X-ray (EDX), or the like.

The embodiments of the present disclosure have some advantageous features. By adopting the pre-doping process to form a dopant-rich layer prior to the formation of source/drain regions, the doping profile may be adjusted, the drive currents of the GAA transistors may be increased. The DIBL performance degradation is minor. Furthermore, by adjusting the profiles of the LDD regions as being concave or straight, the DIBL degradation may further be reduced.

In accordance with some embodiments of the present disclosure, a method comprises forming a multilayer stack comprising a plurality of semiconductor nanostructures and a plurality of sacrificial layers, wherein the plurality of semiconductor nanostructures and the plurality of sacrificial layers are located alternatingly; laterally recessing the plurality of sacrificial layers to form first lateral recesses; performing a doping process to dope a first dopant into the first lateral recesses; forming inner spacers in the first lateral recesses; performing an anneal process to diffuse the first dopant into the inner spacers; and forming a source/drain region contacting the inner spacers, wherein the source/drain region is electrically coupled to the plurality of semiconductor nanostructures.

In an embodiment, the doping process comprises generating a plasma from a process gas that comprises the first dopant; and soaking a wafer comprising the multilayer stack in the plasma. In an embodiment, the doping process is performed without bias power applied. In an embodiment, the source/drain region comprises a second dopant of a same conductivity type as the first dopant. In an embodiment, the doping process generates a conformal dopant layer on surfaces of the plurality of sacrificial layers. In an embodiment, the doping process is performed before the inner spacers are formed.

In an embodiment, the doping process results in a dopant layer to be formed on surfaces of the plurality of semiconductor nanostructures, and wherein the method further comprises performing an etching process to remove the dopant layer from the plurality of semiconductor nanostructures. In an embodiment, the etching process results in second lateral recesses to be generated between the inner spacers, and wherein the source/drain region fills the second lateral recesses.

In an embodiment, after the source/drain region is formed, a source/drain extension region is formed as a part of the source/drain region, and wherein the source/drain extension region comprises a sidewall contacting a channel region in one of the plurality of semiconductor nanostructures, and the sidewall is a concave sidewall. In an embodiment, after the source/drain region is formed, a source/drain extension region is formed as a part of the source/drain region, and wherein the source/drain extension region comprises a sidewall contacting a channel region in one of the plurality of semiconductor nanostructures, and the sidewall is a straight sidewall.

In accordance with some embodiments of the present disclosure, a method comprises forming a first semiconductor layer; forming a sacrificial layer over the first semiconductor layer; forming a second semiconductor layer over the sacrificial layer; laterally recessing the sacrificial layer to form a lateral recess between the first semiconductor layer and the second semiconductor layer; doping a dopant to a first sidewall portion of the sacrificial layer, wherein the first sidewall portion is exposed to the recess; forming a dielectric inner spacer to fill the lateral recess; and driving the dopant into a second sidewall portion of the dielectric inner spacer, wherein the second sidewall portion contacts the first sidewall portion.

In an embodiment, the method further comprises replacing the sacrificial layer with a portion of a gate stack. In an embodiment, the doping the dopant comprises soaking the first semiconductor layer, the sacrificial layer, and the second semiconductor layer in a radical-containing plasma that comprises the dopant.

In accordance with some embodiments of the present disclosure, a structure comprises a semiconductor stack comprising a first semiconductor nanostructure and a second semiconductor nanostructure overlapping the first semiconductor nanostructure; a gate stack comprising a gate portion between the first semiconductor nanostructure and the second semiconductor nanostructure; an inner spacer higher than the first semiconductor nanostructure and lower than the second semiconductor nanostructure; a dopant-rich layer comprising a first dopant, the dopant-rich layer comprising a first portion at a first sidewall of the inner spacer, wherein the first sidewall contacts the gate portion; a second portion at a top surface of the inner spacer; and a third portion at a bottom surface of the inner spacer; and a source/drain region comprising a second dopant of a same conductivity type as the first dopant, wherein the source/drain region contacts a second sidewall of the inner spacer.

In an embodiment, the source/drain region comprises a source/drain extension region overlapped by the inner spacer, wherein the second portion of the dopant-rich layer comprises a part in the source/drain extension region, and the part has a higher dopant concentration than an additional part of the source/drain extension region, with the additional part being underlying and contacting the third portion of the dopant-rich layer. In an embodiment, the first dopant and the second dopant are p-type dopants. In an embodiment, the first dopant and the second dopant comprise boron.

In an embodiment, the first portion of the dopant-rich layer is a dielectric layer, and the second portion and the third portion of the dopant-rich layer comprise semiconductor portions. In an embodiment, the second portion and the third portion of the dopant-rich layer further comprise dielectric portions. In an embodiment, the structure further comprises a bulk semiconductor substrate underlying the source/drain region; and a refilling semiconductor layer between the bulk semiconductor substrate and the source/drain region, wherein the dopant-rich layer further comprises a fourth portion between the bulk semiconductor substrate and the refilling semiconductor layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a multilayer stack comprising a plurality of semiconductor nanostructures and a plurality of sacrificial layers, wherein the plurality of semiconductor nanostructures and the plurality of sacrificial layers are located alternatingly;
etching a part of the multilayer stack to form a source/drain recess;
performing a radical pre-doping process to dope a dopant into the source/drain recess, wherein the dopant is doped into exposed surface portions of the plurality of semiconductor nanostructures and the plurality of sacrificial layers to form a dopant-rich layer;
performing an anneal process to diffuse the dopant in the dopant-rich layer inwardly; and
after the anneal process, forming a source/drain region filling the source/drain recess, wherein the source/drain region is electrically coupled to the plurality of semiconductor nanostructures.

2. The method of claim 1, wherein the radical pre-doping process comprises:
generating a plasma from a process gas that comprises the dopant; and
filtering the plasma to leave radicals of the dopant, wherein the radicals are applied to the exposed surface portions.

3. The method of claim 1, wherein the dopant is of a same conductivity type as the source/drain region.

4. The method of claim 1 further comprising, before the radical pre-doping process, laterally recessing the plurality of sacrificial layers to form lateral recesses, wherein the radical pre-doping process is performed on recessed sidewall surfaces of the plurality of sacrificial layers.

5. The method of claim 4 further, after the pre-doping process, forming inner spacers in the lateral recesses.

6. The method of claim 5, wherein the anneal process results in the dopant to be diffused into the inner spacers.

7. The method of claim 1 further comprising, after the radical pre-doping process is performed, and before the source/drain region is formed, forming a refilling semiconductor layer at a bottom of the source/drain recess.

8. The method of claim 1, wherein the radical pre-doping process is performed without bias power applied.

9. The method of claim 1, wherein the radical pre-doping process comprising filtering radicals from a plasma generated from a gas that comprises the dopant.

10. A method comprising:
forming a first semiconductor layer;
forming a sacrificial layer over the first semiconductor layer;
forming a second semiconductor layer over the sacrificial layer;
etching the second semiconductor layer, the sacrificial layer, and the first semiconductor layer to form a source/drain recess;
laterally recessing the sacrificial layer to form a lateral recess between the first semiconductor layer and the second semiconductor layer;
performing a radical pre-doping process to dope a dopant into a first sidewall portion of the first semiconductor layer and a second sidewall portion of the sacrificial layer, wherein the second sidewall portion is exposed to the lateral recess;
forming a dielectric inner spacer to fill the lateral recess and contacting the second sidewall portion of the sacrificial layer; and
driving the dopant into the dielectric inner spacer.

11. The method of claim 10, wherein the radical pre-doping process further results in the dopant to be doped into a surface portion of a gate spacer that overlaps the second semiconductor layer.

12. The method of claim 10 further comprising:
removing the sacrificial layer; and
forming a replacement gate stack in a space left by the sacrificial layer.

13. The method of claim 12, wherein at a time after the replacement gate stack is formed, a portion of the dielectric inner spacer comprising the dopant is in contact with the replacement gate stack.

14. The method of claim 10 further comprising laterally recessing the first semiconductor layer and the second semiconductor layer, wherein the first sidewall portion of the first semiconductor layer doped with the dopant is removed.

15. The method of claim 10 further comprising forming a source/drain region in the source/drain recess.

16. The method of claim 15, wherein the dopant is of a same conductivity type as the source/drain region.

17. A method comprising:
forming a sacrificial layer;
forming a semiconductor layer over the sacrificial layer;
performing a radical pre-doping process to dope a dopant into a first sidewall portion of the semiconductor layer and a second sidewall portion of the sacrificial layer;
after the radical pre-doping process, forming a dielectric inner spacer joining the second sidewall portion of the sacrificial layer; and
performing an anneal process to drive the dopant;
removing the first sidewall portion of the semiconductor layer that comprises the dopant; and
forming a source/drain region joined to the semiconductor layer, wherein the dopant is of a same conductivity type as the source/drain region.

18. The method of claim 17, wherein the anneal process is performed after the dielectric inner spacer is formed.

19. The method of claim 17, wherein the anneal process is performed before the dielectric inner spacer is formed.

20. The method of claim 17, wherein the dopant in the second sidewall portion of the sacrificial layer is diffused by the anneal process into a surface portion of the dielectric inner spacer, and wherein the method further comprises:
replacing the sacrificial layer with a replacement gate stack, wherein the surface portion of the dielectric inner spacer is in contact with the replacement gate stack.
